(19) United States
(12) Patent Application Publication
(10) Pub. No.: US 2026/0247980 A1
(43) Pub. Date: Aug. 20, 2026

(54) Anti-Radiation Field Effect Transistor Device and Application Thereof in Anti-Radiation Environment

(71) Applicant: Soochow University, Suzhou City, Jiangsu Province (CN)

(72) Inventors: Mingxiang Wang, Suzhou City (CN); Huifang Xu, Suzhou City (CN); Guoao Zhou, Suzhou City (CN); Dongli Zhang, Suzhou City (CN); Huaisheng Wang, Suzhou City (CN)

(21) Appl. No.: 18/995,267

(22) PCT Filed: Oct. 28, 2022
(86) PCT No.: PCT/CN2022/128338

§ 371 Date: Jan. 16, 2025

(51) Int. Cl. H10W 42/20; H10D 30/63; H10D 86/00

(52) U.S. Cl. CPC H10W 42/20; H10D 30/637; H10D 86/201

(57) ABSTRACT

The present invention provides an anti-radiation field effect transistor device and application thereof in an anti-radiation environment, which are used for solving the problem that an anti-radiation method of a field effect transistor in the prior art is limited. The field effect transistor device includes a substrate; a spacer disposed on the substrate; a semiconductor stack disposed on the spacer, wherein the semiconductor stack includes an active layer disposed on the spacer, the active layer including a source region, a drain region and a channel region between the source region and the drain region; and a gate structure matched with the active layer. In a direction perpendicular to the substrate, the spacer is disposed around the semiconductor stack; the spacer includes an electric field adjustment part which intrudes into the channel region in the thickness direction of the active layer; and the electric field adjustment part penetrates through the channel region in the width direction of the active layer.

### TECHNICAL FIELD

The present invention specifically relates to an anti-radiation field effect transistor device and application thereof in an anti-radiation environment, which belongs to the technical field of semiconductor devices.

### BACKGROUND ART

Transistors are widely used in aerospace and electronic equipment. When these devices are exposed to high-energy rays and particles, they will generate trapped charges at oxide layers and material interfaces. Trapped charge accumulation under a high radiation dose will have a very serious impact on the lifetime, reliability and functions of the devices, which is a destructive effect that leads to degradation and even failure of the devices.

With the decrease of a device process feature size, a gate oxide layer becomes much thinner, which makes the number of trapped charges generated in the gate oxide layer by radiation much less. When the thickness of gate oxide layer is less than 10 nm, the influence of gate oxide layer is not considered because the trapped charges induced by radiation can be ignored. Aiming at the buried oxide of SOI (silicon-on-insulator) devices, the present anti-radiation reinforcement measures include oxide burying by high-dose silicon ion implantation. The silicon ion implantation can generate electron traps with a large trap cross section, which can trap electrons to compensate for the trapped positive charge caused by the total ionizing dose effects in buried oxide. Aiming at field oxide of FDSOI (fully depleted SOI) devices, the gate structure is changed to H-gate, ring gate, heavily doped P+ isolation and Z-gate anti-radiation reinforcement structures. These reinforced structures essentially reduce the degradation of device characteristic parameters caused by radiation-induced trapped charges by blocking the conduction of field-oxide sidewall parasitic transistor under irradiation.

### SUMMARY OF THE INVENTION

A purpose of the present invention is to provide an anti-radiation field effect transistor device, which is used to solve the problem that an anti-radiation method of a field effect transistor in the prior art is narrow.

To achieve the above purpose, the present invention provides an anti-radiation field effect transistor device, which includes: a substrate; a spacer disposed on the substrate; a semiconductor stack disposed on the spacer, wherein the semiconductor stack includes an active layer disposed on the spacer, with the active layer including a source region, a drain region and a channel region between the source region and the drain region; and a gate structure matched with the active layer.

In a direction perpendicular to the substrate, the spacer is disposed around the semiconductor stack; the spacer includes an electric field adjustment part which intrudes into the channel region in the thickness direction of the active layer; and the electric field adjustment part penetrates through the channel region in the width direction of the active layer.

In an embodiment, a normal electric field intensity of at least part of an interface between the electric field adjustment part and the active layer is smaller than a reference electric field intensity, wherein the reference electric field intensity is a normal electric field intensity of an interface between the part of the spacer except the electric field adjustment part and the active layer.

In an embodiment, the material of the electric field adjustment part is one or a combination of SiO₂, Si₃N₄, SiOₓN_{y}, HfO₂ and Al₂O₃.

In an embodiment, the electric field adjustment part has a gradually decreasing cross-sectional area, a gradually increasing cross-sectional area or a constant cross-sectional area in a direction away from the substrate.

In an embodiment, the gate structure is able to control the channel region and form a channel connecting the source region and the drain region therein; and the electric field adjustment part is spaced from the channel in the thickness direction.

In an embodiment, a length ratio of the electric field adjustment part to the channel region is 1:1 to 1:3, preferably 1:1 to 1:2.5, and further preferably 1:2.

In an embodiment, when the device is turned on, an effective channel is formed in the channel region; an equivalent source region and/or an equivalent drain region away from the effective channel at least in the thickness direction of the channel region are formed in the channel region; and the field effect transistor device connects the source region and the drain region through the effective channel and the equivalent source region and/or the equivalent drain region to contribute a working current.

Preferably, on the plane perpendicular to the length direction of the effective channel, vertical projections of the equivalent source region and the equivalent drain region are located within a vertical projection of the electric field adjustment part.

In an embodiment, a conductive region not connected with the source region and the drain region is formed in the channel region; wherein when the conductive region is connected with the source region, the conductive region constitutes the equivalent source region; and/or, when the conductive region is connected with the drain region, the conductive region constitutes the equivalent drain region.

In an embodiment, vertical projections of the gate structure and the conductive region on the channel region overlap; wherein the gate structure is able to control the channel region and form a channel therein; and the part in the channel that does not overlap with the vertical projection of the conductive region on the channel region constitutes the effective channel.

The present invention further provides application of a field effect transistor device in an anti-radiation environment. The field effect transistor is the anti-radiation field effect transistor device as described above.

Compared with the prior art, in the embodiments of the present invention, the electric field adjustment part which intrudes into the channel region in the thickness direction of the active layer is disposed in the spacer of the device; and the electric field adjustment part penetrates through the channel region in the width direction of the active layer. In this way, the electric field in the corresponding part of the spacer can be changed at the contact interface between the electric field adjustment part and the active layer, so that the concentration of trapped charges at the interface between the electric field adjustment part and the active layer is lower. Thus, degradation of device characteristics is small; and radiation resistance of the device is enhanced.

### BRIEF DESCRIPTION OF THE DRAWINGS

FIGS. 1-7 are structural schematic diagrams of anti-radiation field effect transistor devices according to different embodiments of the present invention;

FIGS. 8-10 are structural schematic diagrams of conductive regions formed in anti-radiation field effect transistor devices according to different embodiments of the present invention;

FIGS. 11-14 are structural schematic diagrams of anti-radiation field effect transistor devices according to different embodiments of the present invention;

FIGS. 15-22 are schematic diagrams showing the principle of making conductive regions according to embodiments of the present invention;

FIGS. 23-25 are structural schematic diagrams of SOI devices to which a solution of the present invention is applied;

FIG. 26 is a structural schematic diagram showing that an effective channel of an anti-radiation field effect transistor device and a vertical projection of a conductive region on a channel region are spaced according to an implementation of the present invention;

FIGS. 27-31 are comparative diagrams of transfer characteristics of devices in simulation example 1-simulation example 5, respectively;

FIGS. 32-33 are simulation diagrams of interface trapped charges and interface normal electric field intensities of an active layer and a first part of a spacer along the length direction of a channel in simulation example 6 of the present invention, respectively; and

FIGS. 34-35 are simulation diagrams of interface trapped charges and interface normal electric field intensities of an active layer and a second part of a spacer along the length direction of a channel in simulation example 6 of the present invention, respectively.

### DETAILED DESCRIPTION OF THE INVENTION

Typical embodiments embodying the features and advantages of the present invention will be described in detail in the following description. It should be understood that the present invention can be varied in different embodiments without departing from the scope of the present invention, and the description and drawings therein are for illustration in nature, not for limitation of the present invention.

Unless otherwise defined, all technical and scientific terms used in this specification have the same meaning as commonly understood by those skilled in the technical field of the present invention. The terminology used in the specification of the present invention is only for the purpose of describing specific embodiments, and is not intended to limit the present invention.

Referring to FIG. 1, a specific embodiment of an anti-radiation field effect transistor device 100 of the present invention is introduced. In this embodiment, the anti-radiation field effect transistor device 100 includes a substrate 40, a spacer 30, and a semiconductor stack.

In some embodiments, the substrate 40 may include an elemental semiconductor (including silicon or germanium in a crystalline, polycrystalline or amorphous structure); a compound semiconductor (including silicon carbide, gallium arsenide, gallium phosphide, indium phosphide, indium arsenide and indium antimonide); an alloy semiconductor (including SiGe, GaAsP, AlInAs, AlGaAs, GaInAs, GaInP and GainASP); and any other suitable materials or combinations thereof. In some embodiments, the substrate 40 may include a P-type material; and in other embodiments, the substrate 40 may include an N-type material.

The spacer 30 is disposed on the substrate 40; and the semiconductor stack is disposed on the spacer 30. In this embodiment, the semiconductor stack includes an active layer 10 and a gate structure 20. The spacer 30 is at least used to separate semiconductor stacks between different devices; and together with the substrate 40, it forms a semiconductor structure on an insulating layer (SOI, that is, the semiconductor stack made on the insulating layer).

Specifically, the active layer 10 is disposed on the spacer 30; and the material of the active layer 10 may be the same as or different from that of the original substrate 40. Growth of the active layer 10 may be performed by a known semiconductor growth method, such as chemical vapor deposition, including epitaxial growth. The active layer 10 includes a source region 101, a drain region 102, and a channel region 103. The source region 101 and the drain region 102 are located on both sides of the active layer 10, respectively; and the channel region 103 is located between the source region 101 and the drain region 102.

The gate structure 20 is able to control formation of a channel connecting the source region 101 and the drain region 102 in the channel region 103 of the field effect transistor device 100, so that the device is turned on. Specifically, that gate structure 20 includes a gate insulating layer 22 and a gate 21 disposed on the gate insulating layer 22. In some embodiments, the gate insulating layer 22 may be formed of a high-k material, such as zirconium dioxide (ZrO₂), aluminum oxide (Al₂O₃), hafnium oxide (HfO₂), tantalum oxide (Ta₂O₅), hafnium silicon oxide (HfSiO), hafnium silicon oxynitride (HfSiON), hafnium tantalum oxide (HfTaO), hafnium titanium oxide (HfTiO), hafnium zirconium oxide (HfZrO), zirconium silicate, zirconium aluminate, silicon nitride, SiON, titanium oxide, HfO₂—Al₂O₃ alloy, their combinations, etc. In some embodiments, the gate 21 may include metal such as aluminum, titanium, copper, tungsten, tantalum, etc. or doped polysilicon.

In this embodiment, in a direction perpendicular to the substrate 40 (i.e., a plan view direction with respect to the substrate 40), the spacer 30 is further disposed around the semiconductor stack. Therefore, the spacer 30 can be regarded as isolating the semiconductor stack in at least two aspects: on the one hand, the spacer 30 includes a first part 301 located between the substrate 40 and the semiconductor stack, thereby isolating the semiconductor stack from the substrate 30; and on the other hand, the spacer 30 further includes a second part 302 and a third part 303 disposed around the semiconductor stack, thereby isolating the semiconductor stack from other semiconductor stacks at the side.

It should be noted that the first part 301, the second part 302 and the third part 303 in the spacer 30 do not mean that the spacer is divided into different parts in structure or material, but only for convenience of description. Illustratively, the second part 302 and the third part 303 in the spacer 30 can be formed at one time in some embodiments, and can be of the same material. Surely in some embodiments, the first part 301 of the spacer 30 may be made of a material different from those of the second part 302 and the third part 303, and shaped by different steps.

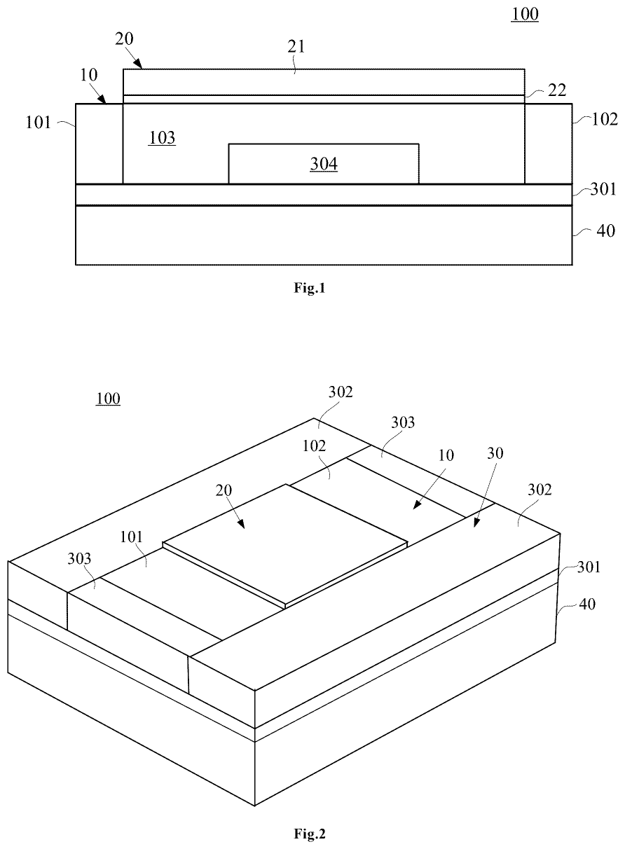

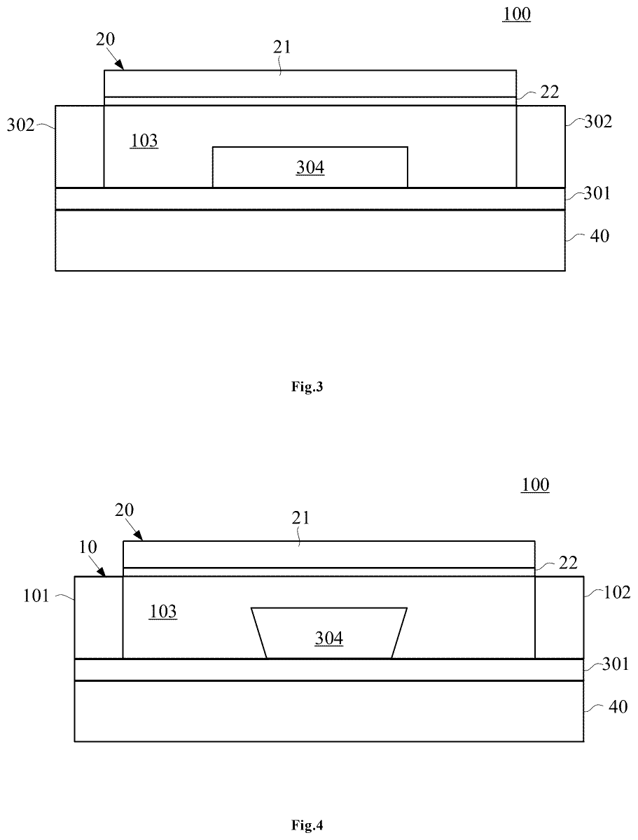

Referring to FIG. 2 and FIG. 3 together, specifically, the first part 301 of the spacer 30 may be formed of, for example, SiO₂, HfO₂, Al₂O₃ or other suitable oxide materials. Illustratively, in the silicon substrate 40, the first part 301 may be a silicon oxide layer. For example, the first part 301 may be formed by implanting oxygen ions through the top surface of the substrate 40 in the thickness direction of the silicon substrate 40, and then annealing the silicon substrate 40 with the implanted oxygen ions. The first part 301 may be formed substantially parallel to the top surface of the substrate 40; and the distance from the top surface is smaller than the thickness of the substrate 40. The first part 301 may extend in at least one horizontal direction, that is, a direction parallel to the top surface of the substrate 40.

Further, the second part 302 and the third part 303 may be formed in a trench by depositing an insulating material filling the trench on the first part 301 (for example, using a CVD process or a spin-on glass process) and performing a chemical mechanical polishing (CMP) process to remove the excess insulating material and/or planarization. The deposition process may be a flowable CVD (FCVD) process, a high aspect ratio deposition (HARP) process, a high density plasma CVD (HDPCVD) process, other suitable deposition processes, or a combination thereof.

In some embodiments, the second part 302 and the third part 303 of the spacer 30 may have a multilayer structure, such as an oxide layer disposed over a silicon nitride liner. In some embodiments, the second part 302 and the third part 303 include a dielectric layer disposed over a doped liner (including, for example, borosilicate glass (BSG) or phosphosilicate glass (PSG)). In some embodiments, the second part 302 and the third part 303 include a bulk dielectric layer disposed over a dielectric liner. The second part 302 and the third part 303 include silicon oxide, silicon nitride, silicon oxynitride, other suitable isolation materials (including, for example, silicon, oxygen, nitrogen, carbon or other suitable isolation components) or a combination thereof. The second part 302 and the third part 303 may be configured as a shallow trench isolation (STI) structure, a deep trench isolation (DTI) structure, a local oxidation of silicon (LOCOS) structure and/or other suitable isolation structures.

The spacer 30 includes an electric field adjustment part 304 which intrudes into a channel region 103 in the thickness direction of the active layer 10; and the electric field adjustment part 304 penetrates through the channel region 103 in the width direction of the active layer 10. It can be understood that the intrusion of the spacer 30 here is not “getting through” the thickness direction of the active layer 10; and the intrusion of the spacer 30 should not affect the formation of the channel when the device is turned on.

In each embodiment of the present invention, the direction from a source region 101 to a drain region 102 of the active layer 10 is called the length direction of the active layer 10; the direction perpendicular to the substrate 40 is called the thickness direction of the active layer 10; and the width direction of the active layer 10 is the direction perpendicular to the length direction of the active layer 10. Correspondingly, the electric field adjustment part 304 penetrates through the channel region 103 in the width direction of the active layer 10 also means the electric field adjustment part 304 is connected with the second part 302.

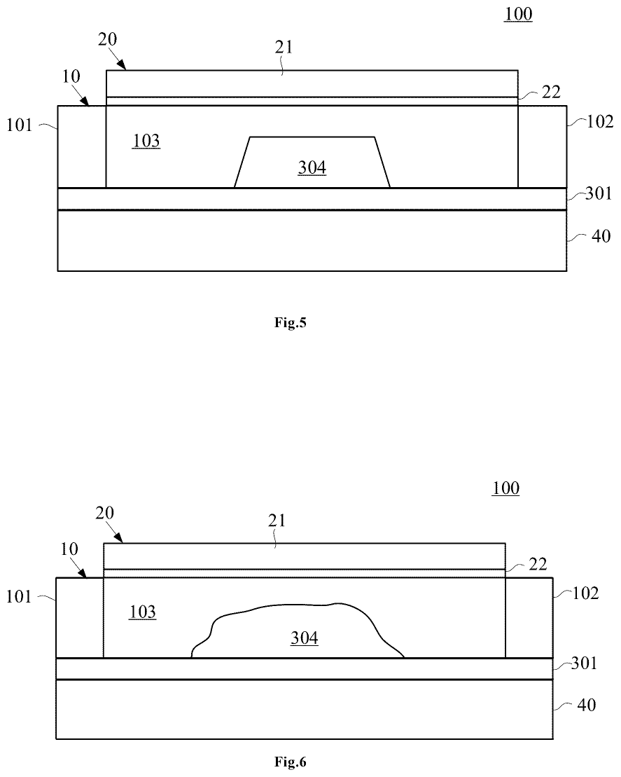

In each embodiment of the present invention, the specific shape of the electric field adjustment part 304 is not limited. The electric field adjustment part 304 may have a regular shape as a whole, such as a rectangular solid shape shown in FIG. 1, an inverted trapezoid shape shown in FIG. 4 and a regular trapezoid shape shown in FIG. 5. One face of the electric field adjustment part 304 is in contact with the first part 301 of the spacer 30. In the embodiment shown in FIG. 4, the electric field adjustment part 304 has a gradually increasing cross-sectional area in the direction away from the substrate 40. In the embodiment shown in FIG. 5, the electric field adjustment part 304 has a gradually decreasing cross-sectional area in the direction away from the substrate 40. In the embodiment shown in FIG. 1, the electric field adjustment part 304 has a constant cross-sectional area in the direction away from the substrate 40. Alternatively, the electric field adjustment part 304 may have an irregular shape, such as the embodiment shown in FIG. 6.

On the basis of the above structure disclosed in the embodiments of the present invention, a normal electric field intensity of at least part of an interface between the electric field adjustment part 304 and the active layer 10 is smaller than a reference electric field intensity, wherein the reference electric field intensity is a normal electric field intensity of an interface between the part of the spacer 30 except the electric field adjustment part 304 and the active layer 10. That is, arrangement of the electric field adjustment part 304 is equivalent to changing the electric field in the corresponding part of the spacer 30 at the contact interface between the electric field adjustment part 304 and the active layer 10, which will lead to a lower concentration of trapped charges at the interface between the electric field adjustment part 304 and the active layer 10, thereby reducing degradation of device characteristics and enhancing anti-radiation characteristics of the device. Understandably, the interface trapped charges described here originate from ionized charges excited by irradiation of the spacer 30.

In some embodiments, the material of the electric field adjustment part 304 may be one or a combination of SiO₂, Si₃N₄, SiOₓN_{y}, HfO₂ and Al₂O₃. In terms of size, a length ratio of the electric field adjustment part 304 to the channel region 103 is 1:1 to 1:3, preferably 1:1 to 1:2.5, and further preferably 1:2. The electric field adjustment part 304 is spaced from the channel in the thickness direction, that is, when the gate structure 20 controls the channel region 103 and forms the channel 104 therein, it is advisable to dispose the electric field adjustment part 304 without affecting formation of the channel 104. On this premise, the greater the thickness of the electric field adjustment part 304 is, the better the radiation resistance of the device will be. Of course, in different embodiments, the material of the electric field adjustment part 304 may be the same as or different from any one of the first part 301, the second part 302 and the third part 303 in the spacer 30 according to needs and selection of the device.

In some embodiments, the electric field adjustment part 304 of a suitable dielectric material can be formed on the substrate 40 by processes such as deposition and etching, and then the active region 10 of the device can be generated on the substrate 40 where the electric field adjustment part 304 has been formed. In other embodiments, taking the silicon substrate 40 as an example, the first part 301 of the spacer 30 of part of the width in part of the region may be removed by etching and other processes after the first part 301 of the spacer 30 is formed by oxygen ion implantation; and a structure integrating the first part 301 of the spacer 30 and the electric field adjustment part 304 is obtained.

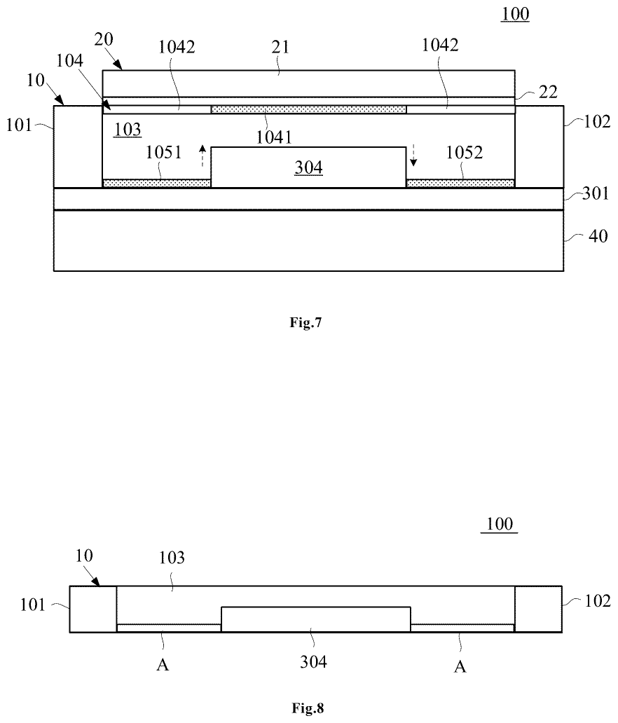

Referring to FIG. 7, another embodiment of the anti-radiation field effect transistor device 100 of the present invention will be described. Different from the previous embodiment, in this embodiment, when the device is turned on, an effective channel 1041 and an equivalent source region 1051 and an equivalent drain region 1052 away from the effective channel 1041 in the thickness direction of the channel region 103 are formed in the channel region 103; and the field effect transistor device 100 connects the source region 101 and the drain region 102 through the effective channel 1041, the equivalent source region 1051 and the equivalent drain region 1052 to contribute a working current.

In some embodiments of the present invention, the “distance” between the effective channel 1041 and the equivalent source region 1051 and the equivalent drain region 1052 may include the distance in the length direction of the channel region as well as in the thickness direction of the channel region. In these embodiments, no matter the distance in the thickness or length direction of the channel region, it is limited that connection of the effective channel 1041, the equivalent source region 1051, and the equivalent drain region 1052 with the source region 101 and the drain region 102 is not influenced when the device is turned on.

In a typical field effect transistor device 100, the source region 101 in the active layer 10 is used to provide carriers when the device is turned on; and the drain region 102 is used to collect the carriers provided by the source region 101. Correspondingly, in the present invention, the equivalent source region 1051 refers to a structure in which part of the carriers provided by the source region 101 are directly injected into the effective channel 1041. The equivalent drain region 1052 refers to a structure in which part of the carriers are directly received from the effective channel 1041 and injected into the drain region 102.

The “effective channel 1041” mentioned in the present invention refers to a part of the channel through which the carriers as the working current will pass when the device is turned on. In this embodiment, the gate structure 20 can form a channel 104 below it through control; and the channel 104 is correspondingly and structurally connected to the source region 101 and the drain region 102. However, from the functional point of view, only the part of the channel 104 that does not overlap with the vertical projection of the equivalent source region 1051 and the equivalent drain region 1052 on the channel region 103 is used to transmit all the working current. Hence, only this part of the channel will be called the “effective channel 1041” here.

In this implementation, a carrier path when the device is turned on includes two main parts: one part enters the equivalent source region 1051, the effective channel 1041, the equivalent drain region 1052 and the drain region 102 from the source region 101 in turn; and the other part directly enters the drain region 102 from the source region 101 through the channel 104. As for the carrier path, the remaining channels in the channel 104 except the effective channel 1041 are only used to transmit part of the working current.

It can be found that the effective channel 1041 in the present invention is not limited to having different device structures or parameter settings from the remaining part of the channel 104. In fact, in some embodiments, the above-mentioned channel 104 can be formed on the whole channel region. Only by setting the equivalent source region 1051 and the equivalent drain region 1052, the carriers provided by the source region 101 will not be directly injected into the drain region 102 through the channel 104 when the device is turned on. Therefore, the regulation of the channel that may be shown in the following embodiments, such as changing a work function of the gate structure corresponding to the effective channel and the thickness of the gate insulating layer, should not be regarded as a necessary prerequisite for formation of the effective channel.

The arrangement of the equivalent source region 1051 and the equivalent drain region 1052 is equivalent to shortening the length of the part of the channel 104 that can completely conduct the working current, that is, an interval is generated between the effective channel 1041 and the source region 101 and the drain region 102. Moreover, the equivalent drain region 1052 connected with the drain region 102 is structurally away from the effective channel 1041, thereby reducing the influence of the drain potential on the effective channel 1041. The equivalent source region 1051 connecting with the source region 101 is away from the effective channel 1041 in structure; and the potential of the equivalent source region 1051 is consistent with the source region (usually zero potential), which also reduces the influence of the drain potential on the effective channel 1041 to improve a short channel effect of the device.

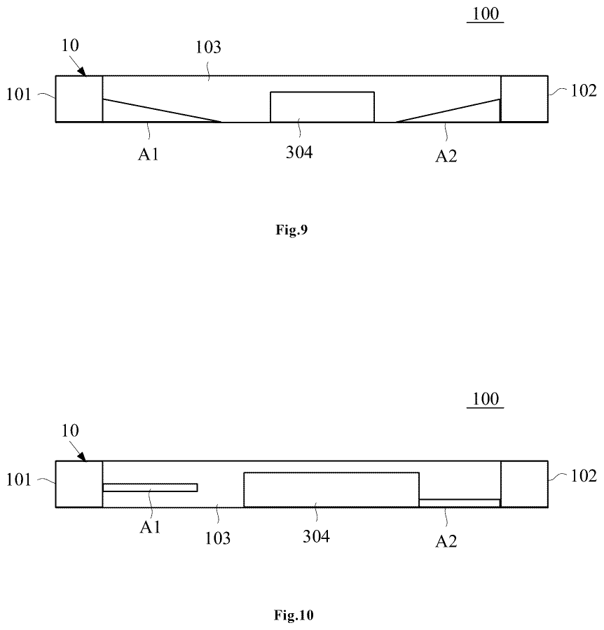

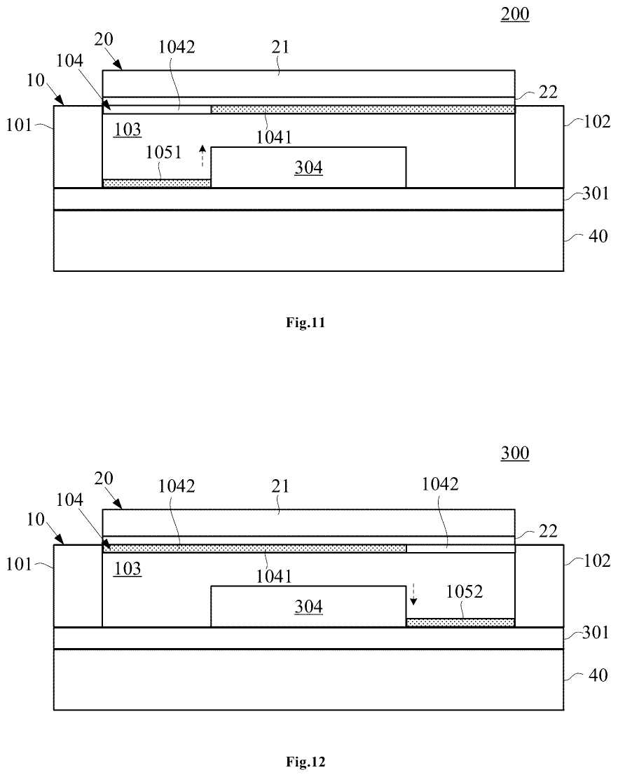

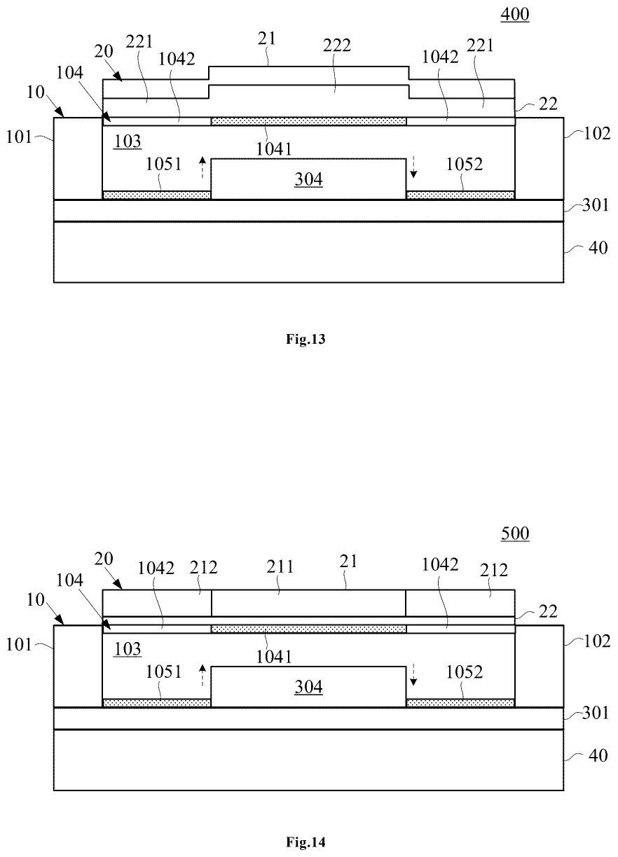

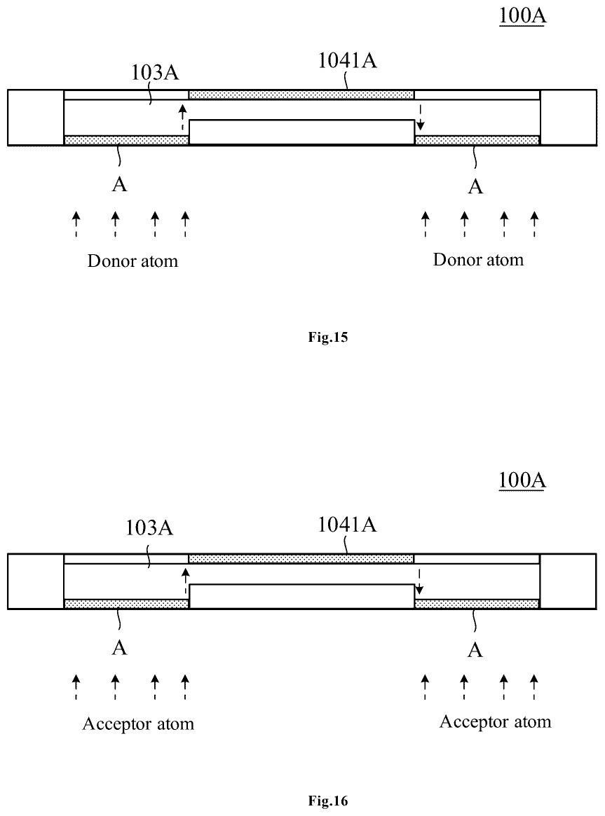

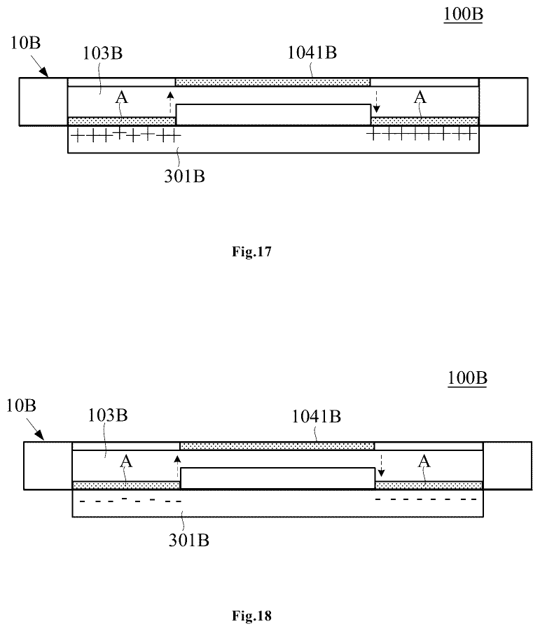

Referring to FIG. 8, in specific preparation of the equivalent source region 1051 and the equivalent drain region 1052, the conductive region A that does not connect the source region 101 and the drain region 102 can be formed in the channel region 103; when the conductive region A is connected with the source region 101, this part of conductive region A constitutes the equivalent source region 1051; and when the conductive region A is connected with the drain region 102, this part of conductive region A constitutes the equivalent drain region 1052.

When the device is turned on, the conductance of the conductive region A could be set to be greater than that of a remaining part 1042 in the channel 104 except the effective channel 1041, so that carriers can be mutually injected between the conductive region A and the effective channel 1041. In this way, the carriers in the source region 101 will be attracted by the equivalent source region 1051 with the greater conductance, and will not be directly injected into the remaining part 1042 directly connected to the source region 101 in the channel 104. Similarly, the carriers transported in the effective channel 1041 will be attracted by the equivalent drain region 1052, but not all of them will be transported through the remaining part 1042 in the channel 104.

In order to realize the carrier injection arrangement among the equivalent source region 1051, the equivalent drain region 1052, and the effective channel 1041 here, the conductance of the conductive region A may be set to be at least three times greater than that of the remaining part 1042 in the channel 104 except the effective channel 1041. Moreover, since carriers will flow in the thickness direction of the channel region 103 during the above-mentioned “injection”, the interval between the conductive region A and the effective channel 1041 in the thickness direction of the channel region 103 in this implementation may be set to 5 nm to 10 μm, or further preferably 10 nm to 1 μm, or further preferably 10 nm to 100 nm according to the specific design of different devices, so as to ensure the normal injection of carriers and performance of the devices.

In different embodiments, the form and position of the conductive region A can be set according to application needs of the device, which is not limited to the form shown in FIG. 3. For example, the conductive regions A1 and A2 in the field effect transistor device 100 shown in FIG. 9 may have a larger overall thickness and an irregular region shape in comparison with FIG. 8. For another example, in the field effect transistor device 100 shown in FIG. 10, the conductive regions A1 and A2 are not located at the same height in the thickness direction of the channel region.

It should be noted that the “carriers” mentioned in the present invention refer to charge particles that can move freely in the corresponding polar channel/conductive region A. Generally, electrons in an N-type channel or holes in a P-type channel are called “carriers” here; and correspondingly, the holes in the N-type channel or the electrons in the P-type channel are not called “carriers” here. Therefore, the effective channel 1041 and the conductive region A in the present invention are set to have a same polarity, so that interaction of the carriers between the two channels can finally and essentially contribute the working current of the device.

It can be seen that when the device is turned off, for example, when the channel 104 is controlled to turn off by the gate structure 20, the effective channel 1041 also “disappears” accordingly. In these implementations, the equivalent source region 1051 and the equivalent drain region 1052 may not disappear with the disappearance of the effective channel 1041, that is, the equivalent source region 1051 and the equivalent drain region 1052 may still exist in the channel region 103 when the device is turned off.

Referring to FIG. 11, another embodiment of the field effect transistor device 200 of the present invention is introduced.

Different from the above embodiments, in this embodiment, when the device is turned on, the equivalent drain region is not formed in the channel region 103 at this time. The field effect transistor device 200 connects the source region 101 and the drain region 102 through the effective channel 1041 and the equivalent source region 1051 to contribute the working current.

In this embodiment, it is equivalent to weakening the influence of the drain potential on the potential near the source of the channel region 103 only by the arrangement of the equivalent source region 1051, thereby improving the short channel effect of the device. Correspondingly, the effective channel 1041 is directly connected to the drain region 102.

When the device is turned on, during carrier transmission, part of the carriers provided by the source region 101 enter the equivalent source region 1051 and are injected into the effective channel 1041 from the end of the equivalent source region 1051 away from the source region 101. The carriers flowing through the effective channel 1041 are injected back into the drain region 102. That is, in this embodiment, only the conductive region unidirectionally injects carriers into the effective channel 1041.

Referring to FIG. 12, another embodiment of the field effect transistor device 300 of the present invention is introduced.

Different from the above embodiments, in this embodiment, when the device is turned on, the equivalent source region is not formed in the channel region 103 at this time. The field effect transistor device 300 connects the source region 101 and the drain region 102 through the effective channel 1041 and the equivalent drain region 1052 to contribute the working current.

In this embodiment, it is equivalent to weakening the influence of the drain potential on the effective channel 1041 only by setting the equivalent drain region 1052, thereby improving the short channel effect of the device. Correspondingly, the effective channel 1041 is directly connected to the source region.

When the device is turned on, during carrier transport, the carriers provided by the source region 101 enter the effective channel 1041; and part of the carriers are injected into the equivalent drain region 1052 from the end of the effective channel 1041 away from the source region 101, and then injected back into the drain region 102. That is, in this embodiment, only the effective channel 1041 unidirectionally injects the carriers into the conductive region.

In the above embodiment, a structure in which a part of the channel formed under the control of the gate structure constitutes an effective channel is shown. In such a structure, in order to further improve the ability of the device to suppress the short channel effect, the conductance per unit length of the effective channel in the channel can be set to be smaller than that of the remaining part of the channel except the effective channel. Some corresponding embodiments are described below.

Referring to FIG. 13, another embodiment of the field effect transistor device 400 of the present invention is introduced.

In this embodiment, the gate structure 20 includes a gate insulating layer 22 and a gate 21; and the thickness of a gate insulating layer 222 corresponding to the effective channel 1041 is greater than the thickness of a gate insulating layer 221 of the remaining part. That is, the gate insulating layer 221 of the corresponding part of the equivalent source region 1051 and the equivalent drain region 1052 is relatively thinned, so that a modulation capability of the corresponding gates of the remaining part of the channel 1042 except the effective channel 1041 to the corresponding part of the channel 1042 can be enhanced, thereby increasing the conductance of the corresponding part of the channel 1042.

Through a coordinated manner, in this embodiment, a dielectric constant of the gate insulating layer 222 corresponding to the effective channel 1041 may also be set to be smaller than that of the gate insulating layer 221 of the remaining part, so as to further increase the conductance of the channel 1042 of the remaining part except the effective channel 1041.

Referring to FIG. 14, another embodiment of the field effect transistor device 500 of the present invention is introduced.

In this embodiment, the gate structure 20 includes a gate insulating layer 22 and a gate 21; and a part 211 corresponding to the effective channel 1041 in the gate 21 and a remaining part 212 are made of different materials, so that the part 211 corresponding to the effective channel 1041 in the gate 21 and the remaining part 212 have different modulation capabilities for the corresponding channels formed; and the unit length conductance of the effective channel 1041 is less than that of the remaining part 1042 in the channel 104 except the effective channel 1041.

In this embodiment, if the field effect transistor device 500 is an N-type device, a work function of the part 211 corresponding to the effective channel 1041 in the gate 21 is set to be greater than that of the remaining part 212 of the gate 21. Correspondingly, if the field effect transistor device 500 is a P-type device, the work function of the part 211 corresponding to the effective channel 1041 in the gate 21 is set to be smaller than that of the remaining part 212 of the gate 21.

Specifically, if it is an N-type device, the part 211 corresponding to the effective channel 1041 in the gate 21 may adopt metal with a large work function, such as gold, platinum, or P-doped (P+) polysilicon, or ITO, RuO2, WN, MON, etc. with a large work function obtained by adjusting the compound composition as the gate material; and the remaining part 212 may adopt metal with a smaller work function such as aluminum, hafnium, titanium, or N-doped (N+) polysilicon, or Ru—Hf, WN, HfN, TiN, TaN, TaSiN, etc. with a smaller work function obtained by adjusting the compound composition as the gate material. If it is a P-type device, the part 211 corresponding to the effective channel 1041 in the gate 21 may adopt metal with a small work function, such as aluminum, hafnium, titanium, or N-type doped (N+) polysilicon, or Ru—Hf, WN, HfN, TiN, TaN, TaSiN, etc. with a small work function obtained by adjusting the compound composition as the gate material; and the remaining part 212 may adopt metal with a large work function such as gold, platinum, or P-doped (P+) polysilicon, or ITO, RuO₂, WN, MON, etc. with a large work function obtained by adjusting the compound composition as the gate material.

Formation modes of the conductive region in the present invention are introduced with some specific examples below:

### Embodiment 1

A conductive region is formed by doping introduced carriers on the surface of a channel region 103A on the side away from an effective channel 1041A.

Correspondingly, referring to FIG. 15, if it is an N-type silicon-based device 100A, the doping concentration of the interface can be changed by doping donor atoms, such as phosphorus and arsenic, on the surface of the channel region 103A away from the effective channel 1041A; and referring to FIG. 16, if it is a P-type silicon-based device 100A, the doping concentration of the interface can be changed by doping acceptor atoms, such as boron, on the surface of the channel region 103A away from the effective channel 1041A.

### Embodiment 2

With reference to FIG. 17 and FIG. 18, a field effect transistor device 100B includes a first part 301B of a spacer disposed the surface of a side of the active layer 10B away from an effective channel 1041B; and a conductive region A is formed on the surface of a side of a channel region by electrostatic induction from implanted charges in a first part 301B.

Correspondingly, referring to FIG. 17, if it is an N-type device, it can be realized by locally injecting positive charges, such as H+ and holes, into the first part 301B; and referring to FIG. 18, if it is a P-type device, it can be realized by locally implanting negative charges, such as F−, Cl−, electrons, etc., into the first part 301B. In this way, high-density fixed charges are formed in the first part 301B; and carriers of the conductive region A are generated in the channel region 103B near the first part 301B by electrostatic induction. It should be noted that “local” here refers to part of the region in the first part 301B corresponding to the channel region where the conductive region A needs to be formed.

In a specific charge implantation process, the charges may be implanted in the first part 301B closer to the channel region 103B, so that the conductive region A formed in the channel region 103B can store more carriers. Of course, in some other alternative embodiments, a “double insulating layer” structure can be adopted, specifically including a charge trapping layer disposed on the surface of the channel region 103B, and a conventional insulating layer covering the charge trapping layer. The charge trapping layer can be made of materials that are easier to store charges, or metal or semiconductor nanoparticles are introduced into it to store charges more stably, thereby ensuring the stability and controllability of carriers in the conductive region.

### Embodiment 3

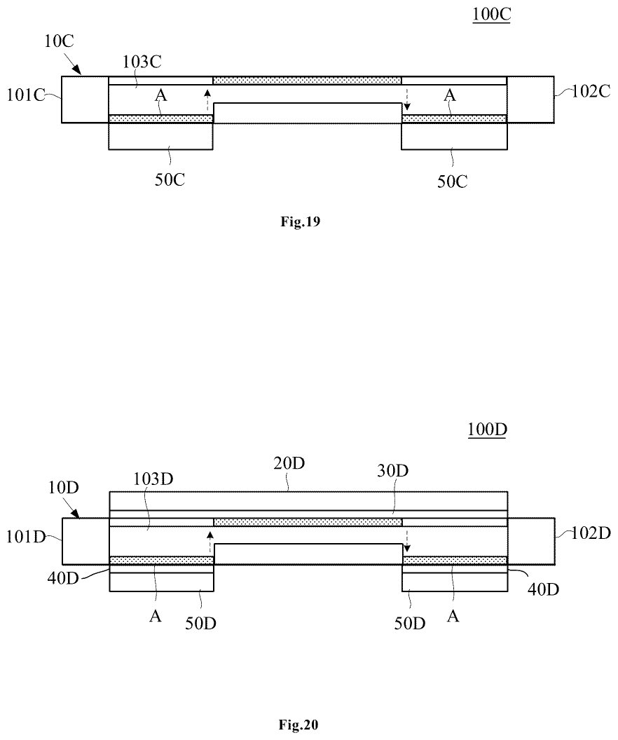

Referring to FIG. 19, a field effect transistor device 100C includes a semiconductor material layer 50C disposed on an active layer 10C, which forms a heterostructure with the active layer 10C; and a conductive region A is formed by two-dimensional electron gas channels or two-dimensional hole gas channels distributed in the heterostructure.

Specifically, the semiconductor material layer 50C and the active layer 10C have different band gap widths; and the semiconductor material layer 50C can be divided into two parts connected to a source region 101C and a drain region 102C respectively, so that the formed two-dimensional electron gas channels will not conduct the source region and the drain region.

Of course, in some alternative embodiments, the two-dimensional electron gas channels or the two-dimensional hole gas channels can be formed by, for example, surface treatment of a channel region 103C. These alternative embodiments of forming the two-dimensional electron gas channels or the two-dimensional hole gas channels, which are familiar to those skilled in the art, should be within the protection scope of the present invention. Moreover, the semiconductor material layer 50C mentioned here may be a barrier layer, which may be doped or intrinsic.

### Embodiment 4

Referring to FIG. 20, a field effect transistor device 100D is made as a device including at least two gates. Specifically, the field effect transistor device 100D includes a first gate insulating layer 30D and a first gate 20D sequentially disposed on the surface of one side of an active layer 10D, and a second gate insulating layer 40D and a second gate 50D sequentially disposed on the surface of one side of the active layer 10D adjacent to the conductive region A.

The second gate 50D is correspondingly divided into two parts, one part of which is vertically projected on the active layer 10D to connect with a source region 101D, and the other part of which is vertically projected on the active layer 10D to connect with a drain region 102D. In this way, when a proper bias voltage is applied to these two parts of the second gate 50D, the conductive regions A connected with the source region 101D and the drain region 102D can be formed at corresponding positions in a channel region 103D.

In this embodiment, an absolute value of the bias voltage applied to the second gate 50D should be greater than an absolute value of a turn-on voltage applied to the device. Correspondingly, if it is an N-type device, a positive bias greater than that of the first gate 20D is applied to the second gate 50D; and if it is a P-type device, a negative bias with the absolute value greater than that of the first gate 20D is applied to the second gate 50D.

### Embodiment 5

Referring to FIG. 21, a field effect transistor device 100E is made to include at least two gates, similar to embodiment 4. However, the difference is that, in this embodiment, in order to make the conductance of a conductive region A larger than that of a part 1042E in a channel 104E except an effective channel 1041E, a first gate 20E and a second gate 50E with different work function gate materials can be adopted. That is, the work function difference between the first gate 20E and an active layer 10E and the work function difference between the second gate 50E and the active layer 10E are not equal.

Correspondingly, if it is an N-type device, the first gate 20E may adopt metal with a large work function such as gold, platinum, or P-doped (P+) polysilicon, or ITO, RuO₂, WN, MoN, etc. with a large work function obtained by adjusting the compound composition as the gate material; and as the gate material, the second gate 50E may adopt metal with a small work function, such as aluminum, hafnium, titanium, or N-doped (N+) polysilicon, or Ru—Hf, WN, HfN, TiN, TaN, TaSiN, etc. with a small work function obtained by adjusting the compound composition. If it is a P-type device, the first gate 20E may adopt metal with a small work function, such as aluminum, hafnium, titanium, or N-type doped (N+) polysilicon, or Ru—Hf, WN, HfN, TiN, TaN, TaSiN, etc. with a small work function obtained by adjusting the compound composition as the gate material; and as the gate material, the second gate 50E may adopt metal with a large work function, such as gold, platinum, or P-doped (P+) polysilicon, or ITO, RuO₂, WN, MoN, etc. with a large work function obtained by adjusting the compound composition.

In an N-type device, it is also possible to set the work function difference between the first gate 20E and the active layer 10E to be greater than zero (φms>0V), so that the channel 104E is an enhanced channel; and meanwhile, the work function difference between the second gate 50E and the active layer 10E is set to be less than zero (φms<0V), so that the conductive region A can also form a certain number of carriers when the second gate 50E is not biased. In a P-type device, the work function difference between the first gate 20E and the active layer can be set to be less than zero (φms<0V), so that the channel 104E is an enhanced channel; and meanwhile, the work function difference between the second gate 50E and the active layer 10E is set to be greater than zero (φms>0V), so that the conductive region A can also form a certain number of carriers when the second gate 50E is not biased.

### Embodiment 6

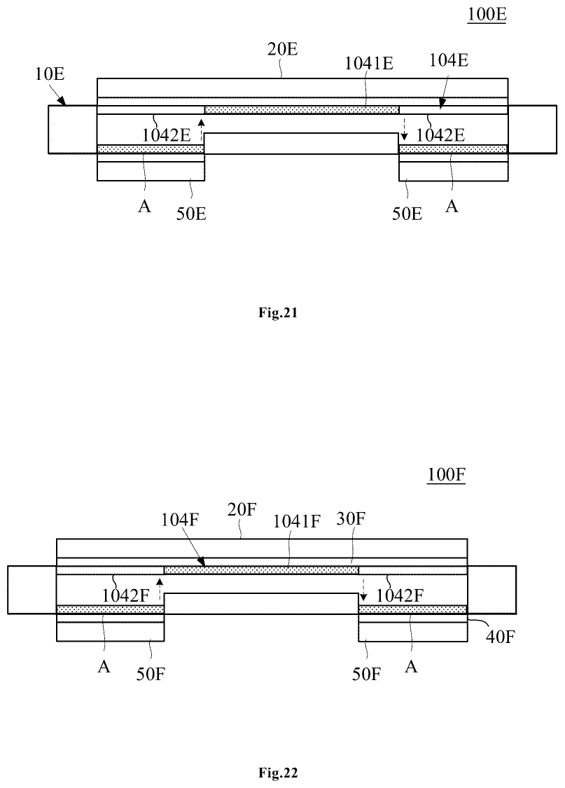

Referring to FIG. 22, a field effect transistor device 100F is made to include at least two gates 20F and 50F, similar to embodiment 4. However, in this embodiment, in order to make the conductance of a conductive region A larger than that of a part 1042F in a channel 104F except an effective channel 1041F, the unit area capacitance of a second gate insulating layer 40F can be set to be larger than that of a first gate insulating layer 30F.

Specifically, it can be achieved by adjusting a dielectric constant of the first gate insulating layer 30F and the second gate insulating layer 40F or the thicknesses of the first gate insulating layer 30F and the second gate insulating layer 40F.

For example, when the thicknesses of the first gate insulating layer 30F and the second gate insulating layer 40F are equal, only the dielectric constant factor of the gate insulating layers may be considered; and the dielectric constant of the second gate insulating layer 40F may be set higher than that of the first gate insulating layer 30F. Illustratively, the first gate insulating layer 30F may use silicon dioxide; and the second gate insulating layer 40F may adopt a medium with a high dielectric constant such as hafnium dioxide, alumina, and the like.

For another example, when the materials of the first gate insulating layer 30F and the second gate insulating layer 40F are the same, the thickness of the second gate insulating layer 40F may be set to be smaller than that of the first gate insulating layer 30F by only considering the thickness factor of the gate insulating layer.

In specific device application, the second gate in the above embodiments 4 to 6 may also be directly floating or grounded, so as to avoid increasing the complexity of the device application due to too many device connection terminals.

Moreover, in the above embodiments, the mode of forming conductive regions can also be combined with each other in application to achieve better embodiment effects.

### Embodiment 7

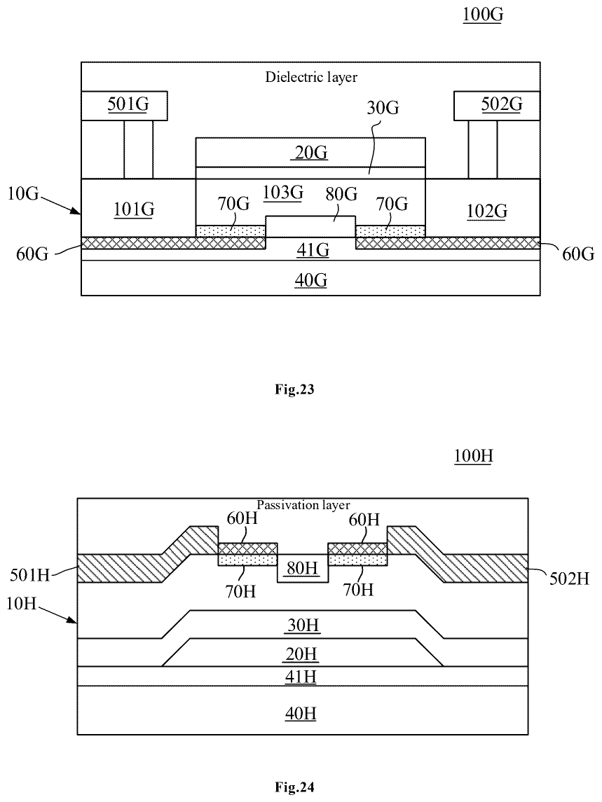

Referring to FIG. 23, a field effect transistor device 100G shown is a planar top gate structure TFT device, and includes a light-transmitting insulating substrate 40G formed with a spacer 41G, and an active layer 10G, a gate dielectric layer 30G, and a gate 20G sequentially disposed on the spacer 41G. Both sides of the active layer 10G are doped to form a source region 101G and a drain region 102G, which are respectively externally connected to a source electrode and a drain electrode; and a channel region 103G is located between the source region 101G and the drain region 102G.

On the spacer 41G, positive charge regions 60G are formed on both sides of the source region 101G and the drain region 102G by ion implantation. There is an overlap part between the positive charge region 60G and the gate 20G in the vertical projection of the channel region 103G. Correspondingly, the positive charge region of the overlap part can form two-dimensional electron gas 70G connected to the source region 101G and the drain region 102G in the channel region 103G, where the two-dimensional electron gas 70G constitutes a conductive region; and a carrier blocking region 80G is formed between the two-dimensional electron gas 70G connected to the source region 101G and the drain region 102G.

When the device is turned on, a channel is formed below the gate 20G; and the part of the channel vertically projected between the conductive regions constitutes an actual effective channel.

### Embodiment 8

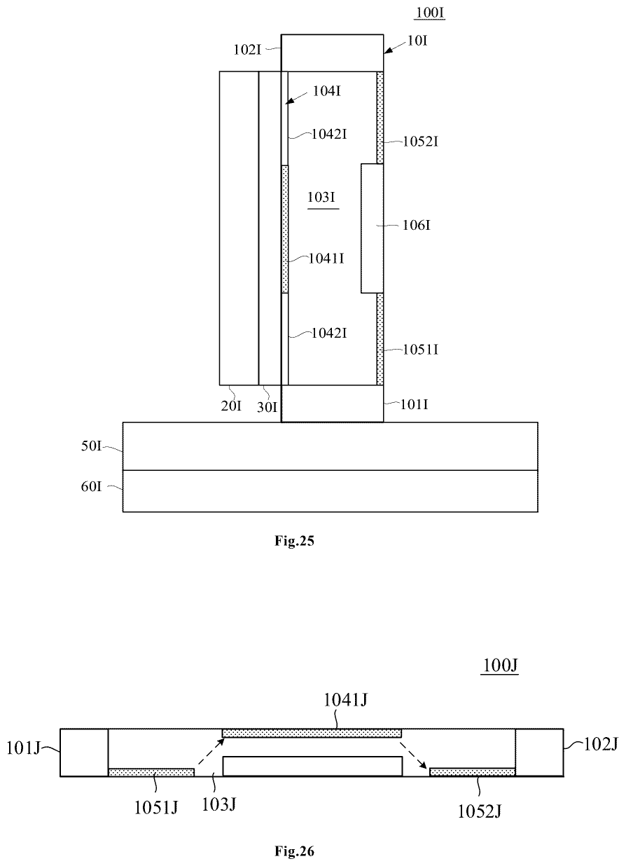

Referring to FIG. 24, it is a planar bottom gate structure TFT device 100H, and includes a light-transmitting insulating substrate 40H formed with a spacer 41H, and a gate 20H, a gate dielectric layer 30H, and an active layer 10H sequentially disposed on the spacer 41H. In this embodiment, an upper metal source electrode 501H and a metal drain electrode 502H are respectively disposed on both sides of the active layer 10H; the active layer 10H may be an amorphous IGZO metal oxide semiconductor layer; and ohmic contact is formed between the source electrode 501H and the drain electrode 502H and the active layer 10H. Part of the active layer under the source electrode 501H and the drain electrode 502H respectively constitute a source region and a drain region; and a channel region is located between the source region and the drain region.

A positive charge region 60H connecting the source electrode 501H and the drain electrode 502H, respectively, is implanted by ion in the passivation layer covered on the upper layer of the device. The positive charge region 60H and the gate 20H have an overlap part between the vertical projections of the channel region. Correspondingly, the positive charge region of the overlap part can form a two-dimensional electron gas 70H connected to the source region and the drain region respectively in the channel region, where the two-dimensional electron gas 70H constitutes a conductive region; and a carrier blocking region 80H is formed between the two-dimensional electron gas 70H connected to the source region and the drain region.

When the device is turned on, a channel is formed above the gate 20H; and the part of the channel vertically projected between the conductive regions 70H constitutes an actual effective channel.

### Embodiment 9

Referring to FIG. 25, it is an SOI device 100I with a vertical structure, and includes a substrate 60I, a spacer 50I and an active layer 10I sequentially disposed on the substrate 60I, a gate insulating layer 30I disposed on one side of the active layer 10I, and a gate 20I. In the direction away from the substrate 60I, a source region 101I and a drain region 102I are located below and above the active layer 10I, respectively. An equivalent source region 1051I connected with the source region 101I and an equivalent drain region 1052I connected with the drain region 102I are formed in a channel region 103I; and a carrier blocking region 106I is formed between the equivalent source region 1051I and the equivalent drain region 1052I.

When a bias voltage is applied to the gate 20I of the device to turn on the device, the gate 20I controls formation of a channel 104I connecting the source region 101I and the drain region 102I in the channel region 103I of the device. However, only the part of the channel 104I that does not overlap with the vertical projection of the equivalent source region 1051I and the equivalent drain region 1052I on the channel region 103I constitutes an effective channel 104I for transmitting a working current when the device is turned on.

In the above embodiments/embodiments, the source region and the drain region in the device may be a common heavily doped semiconductor source and drain, or a Schottky metal source and drain with a metal-semiconductor structure; the gate may be a common metal-insulator-semiconductor MOS structure gate or a Schottky junction gate with a metal-semiconductor structure; the active layer may be composed of a single semiconductor material, or may include at least two semiconductor materials that vary along its thickness direction or plane extension direction to form a composite channel.

Moreover, the equivalent source region and the equivalent drain region can be formed spontaneously, or can be formed through gate control of corresponding structures.

Generally speaking, in the above embodiments, the vertical projection of the effective channel, the equivalent source region and/or the equivalent drain region overlapped on the channel region is connected with the source region and the drain region, thereby ensuring that the carriers of the effective channel and the equivalent source region and/or the equivalent drain region can be injected unidirectionally or bidirectionally at least in the thickness direction, and constructing a carrier path from the source region to the drain region. Of course, referring to FIG. 26, the present invention does not exclude that in some special embodiments, if the vertical projection of the effective channel, the equivalent source region and the equivalent drain region overlapped on the channel region 103J cannot be connected with the source region 101J and the drain region 102J of the device 100J, but has an “appropriate interval”. This interval does not completely cut off the paths of carriers flowing from the equivalent source region 1051J to the effective channel 1041J and from the effective channel 1041J to the equivalent drain region 1052J; and the injection direction of the carriers between the effective channel 1041J, the equivalent source region 1051J and the equivalent drain region 1052J forms an included angle with the thickness direction of the channel region 103J. Such an embodiment should also fall within the protection scope of the present invention.

The following shows results of simulation verification of Sentaurus TCAD by applying the SOI device of the above-mentioned embodiments/embodiments of the present invention.

### Simulation Example 1

In simulation example 1, the SOI device to which the above-mentioned embodiments/embodiments of the present invention are applied is called an “SOI device of the present invention”. As a comparison, it is an SOI device with a similar structure to that of the SOI device of the present invention; the only difference is that there is no electric field adjustment part in the SOI device as a comparison (referred to as the comparative SOI device in this simulation example); and the thickness of an active region of the comparative SOI device is equal to that of the SOI device of the present invention.

Simulation parameters: source-drain doping is N-type with a doping concentration of 1E21 cm⁻³; channel doping is P-type with a doping concentration of 1E17cm⁻³, channel length Lg of 200 nm, active layer thickness of 50 nm, gate insulating layer thickness of 5 nm, thickness of the first part of the spacer of 100 nm, and width of the channel region of 200 nm; and the electric field adjustment part is 60 nm long, 25 nm thick and 200 nm wide.

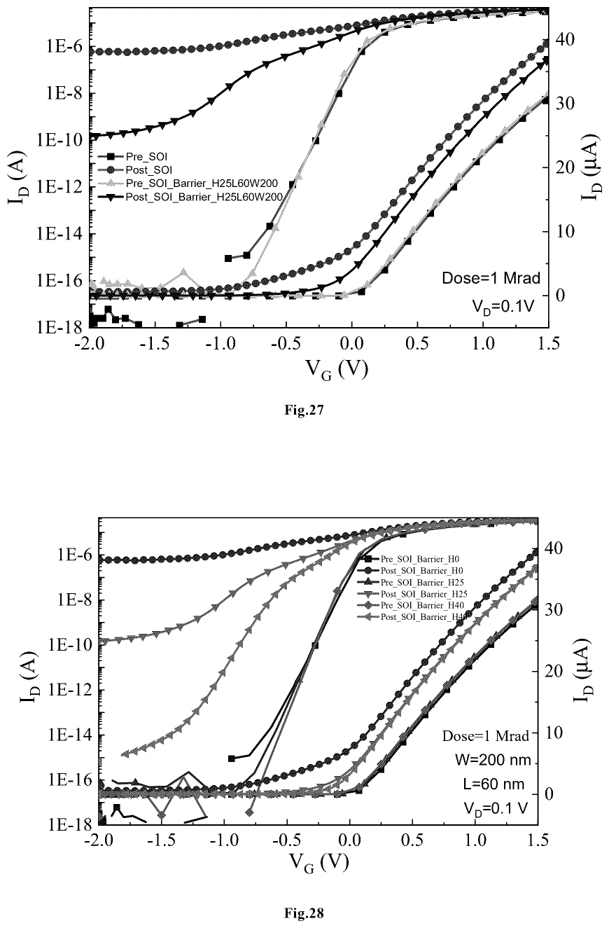

Referring to FIG. 27, taking the total radiation dose of 1Mrad (Si) as an example, Pre_SOI represents characteristics of the comparative SOI device before radiation; Post_SOI represents characteristics of the comparative SOI device after radiation; Pre_SOI_Barrier represents characteristics of the SOI device of the present invention before radiation; and Post_SOI_Barrier represents characteristics of the SOI device of the present invention after radiation. It can be found that, after radiation, the performance of the comparative SOI device is seriously degraded and basically cannot work normally. An off-state current of the SOI device of the present invention after radiation is nearly four orders of magnitude smaller than that of the comparative SOI device; and the offset of a threshold voltage is also smaller than that of the comparative SOI device.

### Simulation Example 2

In simulation example 2, the SOI device to which the above-mentioned embodiments/embodiments of the present invention are applied is called an “SOI device of the present invention”. As a comparison, it is an SOI device with a similar structure to that of the SOI device of the present invention; the only difference is that there is no electric field adjustment part in the SOI device as a comparison (referred to as the comparative SOI device in this simulation example); and the thickness of an active region of the comparative SOI device is equal to that of the SOI device of the present invention.

Simulation parameters: source-drain doping is N-type with a doping concentration of 1E21 cm⁻³; channel doping is P-type with a doping concentration of 1E17cm⁻³, channel length Lg of 200 nm, active layer thickness of 50 nm, gate insulating layer thickness of 5 nm, thickness of the first part of the spacer of 100 nm, and width of the channel region of 200 nm; and the electric field adjustment part is 60 nm long, 200 nm wide and 0nm (i.e. comparative SOI device), 25 nm and 40 nm thick respectively.

Referring to FIG. 28, taking the total radiation dose of 1Mrad (Si) as an example, off-state currents of the SOI device of the present invention after radiation are all better than those of the comparative SOI device; and the off-state current decreases with the increase of the thickness of the electric field adjustment part. When the thickness of the electric field adjustment part is 40 nm, the off-state current of the device is nearly 9 orders of magnitude smaller than that of the comparative SOI device. Moreover, compared with the comparative SOI device, a threshold voltage offset of the device after radiation is not obvious when the electric field adjustment part of the SOI device of the present invention has different thicknesses.

### Simulation Example 3

In simulation example 3, the SOI device to which the above-mentioned embodiments/embodiments of the present invention are applied is called an “SOI device of the present invention”. As a comparison, it is an SOI device with a similar structure to that of the SOI device of the present invention. The only difference is that there is no electric field adjustment part in the SOI device as a comparison (referred to as the comparative SOI device in this simulation example); and the thickness of an active region of the comparative SOI device is equal to that of the SOI device of the present invention.

Simulation parameters: source-drain doping is N-type with a doping concentration of 1E21 cm⁻³; channel doping is P-type with a doping concentration of 1E17cm⁻³, channel length Lg of 200 nm, active layer thickness of 50 nm, gate insulating layer thickness of 5 nm, thickness of the first part of the spacer of 100 nm, and width of the channel region of 200 nm; and the electric field adjustment part is 25 nm thick, 200 nm wide and Onm (i.e. comparative SOI device), 100 nm and 180nm long respectively.

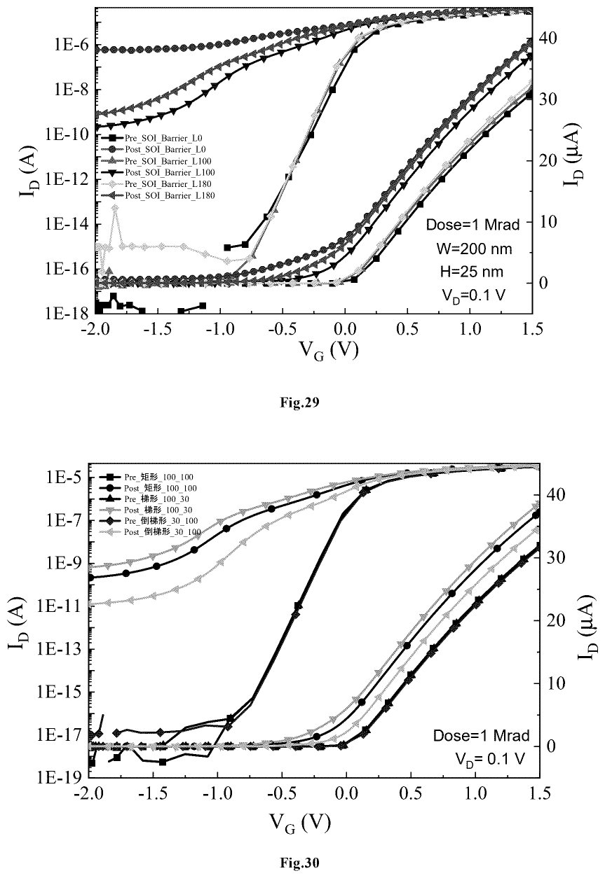

Referring to FIG. 29, taking the total radiation dose of 1Mrad (Si) as an example, off-state currents of the SOI device of the present invention are all better than those of the comparative SOI device; and the drift of a threshold voltage is the smallest when the length of the electric field adjustment part is 100 nm.

### Simulation Example 4

In simulation example 4, the SOI device to which the above-mentioned embodiments/embodiments of the present invention are applied is called an “SOI device of the present invention”.

Simulation parameters: source-drain doping is N-type with a doping concentration of 1E21 cm⁻³; channel doping is P-type with a doping concentration of 1E17 cm⁻³, channel length Lg of 200 nm, active layer thickness of 50 nm, gate insulating layer thickness of 5 nm, thickness of the first part of the spacer of 100 nm, and width of the channel region of 200 nm. Shapes of the electric field adjustment parts are respectively: 1) rectangular solid: 25 nm thick and 100 nm long; 2) trapezoid: 100 nm long in bottom, 30 nm long in top, 25 nm high and 200 nm wide; and 3 inverted trapezoid: 30 nm long in bottom, 100 nm long in top, 25 nm high and 200 nm wide.

Referring to FIG. 30, taking the total radiation dose of 1Mrad (Si) as an example, it can be found that the drift of a threshold voltage of the inverted trapezoid is smaller than that of the rectangle (rectangular solid) and trapezoid; and the off-state current is the smallest, indicating that the characteristics are the best when electric field adjustment part of the SOI device of the present invention has the inverted trapezoid shape.

### Simulation Example 5

In simulation example 5, the SOI device to which the above-mentioned embodiments/embodiments of the present invention are applied is called an “SOI device of the present invention”. As a comparison, it is an SOI device with a similar structure to that of the SOI device of the present invention; the only difference is that there is no electric field adjustment part in the SOI device as a comparison (referred to as the comparative SOI device in this simulation example); and the thickness of an active region of the comparative SOI device is not equal to that of the SOI device of the present invention.

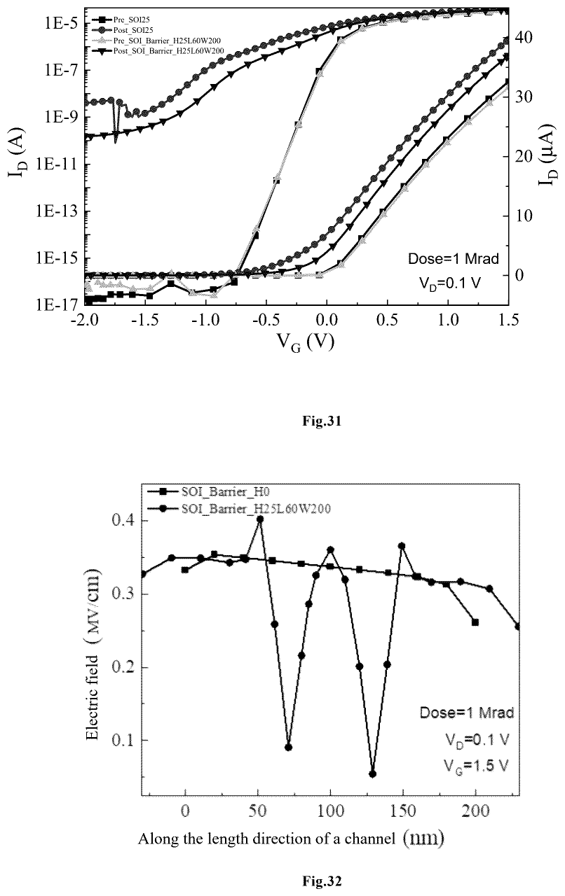

Simulation parameters: source-drain doping is N-type with a doping concentration of 1E21 cm⁻³; channel doping is P-type with a doping concentration of 1E17cm⁻³, channel length Lg of 200 nm, active layer thicknesses of 50 nm (SOI device of the present invention) and 25 nm (comparative SOI device) respectively, gate insulating layer thickness of 5 nm, thickness of the first part of the spacer of 100 nm, and width of the channel region of 200 nm; and the electric field adjustment part is 25 nm thick, 60 nm long, and 200 nm wide. In simulation example 5, the thickness of the active layer in the SOI device of the present invention is the same as that of the comparative SOI device after removing the thickness of the electric field adjustment part. Referring to FIG. 31, taking the total radiation dose of 1Mrad (Si) as an example, it can be found that the characteristics of the SOI device of the present invention after radiation are still better than those of the comparative SOI device.

### Simulation Example 6

In simulation example 6, the SOI device to which the above-mentioned embodiments/embodiments of the present invention are applied is called an “SOI device of the present invention”. As a comparison, it is an SOI device with a similar structure to that of the SOI device of the present invention; the only difference is that there is no electric field adjustment part in the SOI device as a comparison (referred to as the comparative SOI device in this simulation example).

Simulation parameters: source-drain doping is N-type with a doping concentration of 1E21 cm⁻³; channel doping is P-type with a doping concentration of 1E17cm⁻³, channel length Lg of 200 nm, active layer thicknesses of 50 nm, gate insulating layer thickness of 5 nm, thickness of the first part of the spacer of 100 nm, and width of the channel region of 200 nm; and the electric field adjustment part is 25 nm thick, 60 nm long, and 200 nm wide.

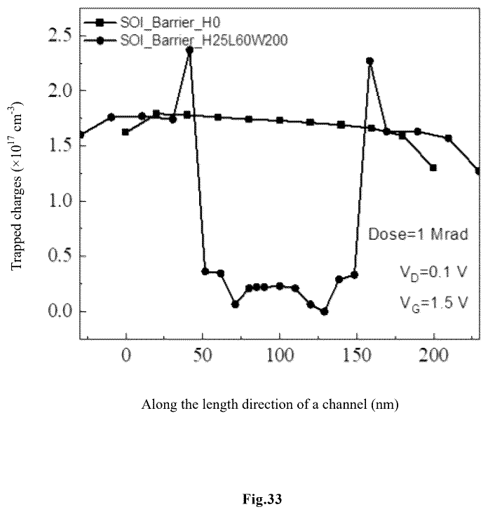

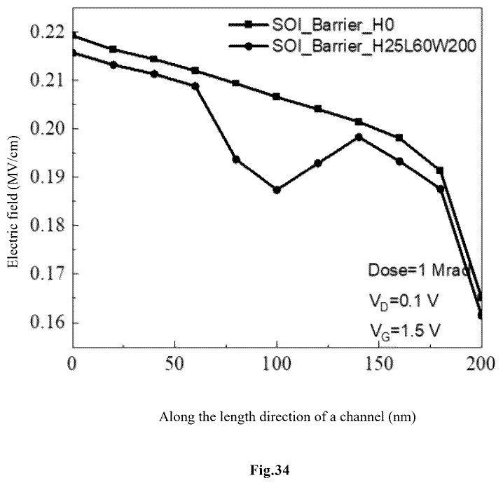

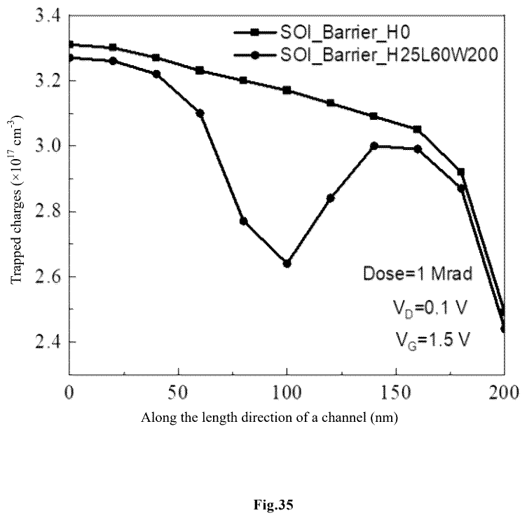

Referring to FIG. 32 to FIG. 35, it can be found that, taking the total radiation dose of 1Mrad (Si) as an example, at the interface between the first part of the spacer and the active layer, and at the interface between the second part of the spacer and the active layer, at least part of the SOI device of the present invention has obvious weakening of the interface normal electric field intensity along the channel direction length corresponding to the position of the electric field adjustment part; and correspondingly, the concentration of trapped charges is also obviously reduced. Meanwhile, although the normal electric field intensity of part of the interface is higher at the position corresponding to the electric field adjustment part, compared with the comparative SOI device, there is still an order of magnitude difference in the concentration of trapped charges. Hence, the SOI device of the present invention maintains a better anti-radiation level as a whole.

The anti-radiation field effect transistor device provided by the above-mentioned embodiments/embodiments can be applied in the anti-radiation environment.

It should be understood that the described embodiments of the present invention are only for illustrative purposes, and are not used to limit the protection scope of the present invention. Those skilled in the art can make various other substitutions, changes and improvements within the scope of the present invention, so the present invention is not limited to the above-mentioned embodiments, but only limited by the claims.

1. An anti-radiation field effect transistor device, comprising:
a substrate;
a spacer disposed on the substrate;
a semiconductor stack disposed on the spacer, wherein the semiconductor stack comprises an active layer disposed on the spacer, the active layer including a source region, a drain region and a channel region between the source region and the drain region; and
a gate structure matched with the active layer,
wherein in a direction perpendicular to the substrate, the spacer is disposed around the semiconductor stack; the spacer comprises an electric field adjustment part which intrudes into the channel region in the thickness direction of the active layer; and the electric field adjustment part penetrates through the channel region in the width direction of the active layer.

2. The anti-radiation field effect transistor device according to claim 1, wherein a normal electric field intensity of at least part of an interface between the electric field adjustment part and the active layer is smaller than a reference electric field intensity, wherein the reference electric field intensity is a normal electric field intensity of an interface between the part of the spacer except the electric field adjustment part and the active layer.

3. The anti-radiation field effect transistor device according to claim 1, wherein the material of the electric field adjustment part is selected from the group consisting of SiO₂, Si₃N₄, SiOₓN_{y}, HfO₂ and Al₂O₃.

4. The anti-radiation field effect transistor device according to claim 1, wherein the electric field adjustment part has a gradually decreasing cross-sectional area, a gradually increasing cross-sectional area or a constant cross-sectional area in a direction away from the substrate.

5. The anti-radiation field effect transistor device according to claim 1, wherein the gate structure is able to control the channel region and form a channel connecting the source region and the drain region therein; and the electric field adjustment part is spaced from the channel in the thickness direction.

6. The anti-radiation field effect transistor device according to claim 1, wherein a length ratio of the electric field adjustment part to the channel region is 1:1 to 1:3.

7. The anti-radiation field effect transistor device according to claim 1, wherein when the device is turned on, an effective channel is formed in the channel region, an equivalent source region and/or an equivalent drain region away from the effective channel at least in the thickness direction of the channel region is/are formed in the channel region; and the field effect transistor device connects the source region and the drain region through the effective channel and the equivalent source region and/or the equivalent drain region, so as to contribute a working current.

8. The anti-radiation field effect transistor device according to claim 7, wherein a conductive region not connected with the source region and the drain region is formed in the channel region; wherein
when the conductive region is connected with the source region, the conductive region constitutes the equivalent source region; and/or,
when the conductive region is connected with the drain region, the conductive region constitutes the equivalent drain region.

9. The anti-radiation field effect transistor device according to claim 8, wherein vertical projections of the gate structure and the conductive region on the channel region overlap with each other; wherein
the gate structure is capable of controlling the channel region and forming a channel therein; and a part in the channel that does not overlap with the vertical projection of the conductive region on the channel region constitutes the effective channel.

10. (canceled)

11. The anti-radiation field effect transistor device according to claim 1, wherein on the plane perpendicular to the length direction of the effective channel, vertical projections of the equivalent source region and the equivalent drain region are located within a vertical projection of the electric field adjustment part.
